(19) United States
(12) Patent Application Publication
(10) Pub. No.: US 2024/0265169 A1
(43) Pub. Date: Aug. 8, 2024

(54) Parameterizable, Software-Implemented Interface for Data Exchange of at Least One Process Variable

(71) Applicant: Robert Bosch GmbH, Stuttgart (DE)

(72) Inventors: Andreas Selig, Lohr Am Main (DE); Joerg Seeger, Bad Koenig (DE); Wolfgang Rueppel, Frammersbach (DE)

(21) Appl. No.: 18/420,476

(22) Filed: Jan. 23, 2024

(30) Foreign Application Priority Data
Feb. 2, 2023 (DE) 10 2023 200 826.2

(51) Int. Cl. G06F 30/20; B60L 15/20

(52) U.S. Cl. CPC G06F 30/20; B60L 15/20

(57) ABSTRACT

A parameterizable software-implemented interface is for data exchange of at least one process variable between a simulation model of a drive controller of an electric drive and a periphery of the drive controller of the electric drive.

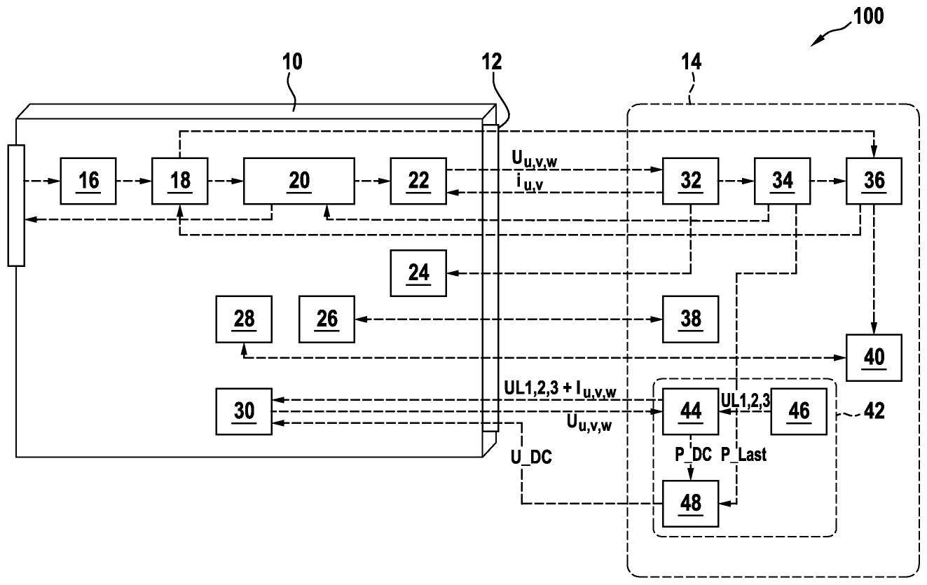

This application claims priority under 35 U.S.C. § 119 to patent application no. DE 10 2023 200 826.2, filed on Feb. 2, 2023 in Germany, the disclosure of which is incorporated herein by reference in its entirety.

The disclosure relates to a parameterizable, software-implemented interface for data exchange of at least one process variable between a simulation model of a drive controller of an electric drive and a periphery of the drive controller of the electric drive.

### BACKGROUND

Electrical drive systems comprising a drive controller and at least one electric machine are well known from the prior art. Such drive systems are of great importance in particular in the course of the extensive electrification of the motor vehicle. The electric machine is controlled by a drive controller. The drive controller comprises drive logic in the form of implemented algorithms executed on a computing device having at least one processor.

In order to correctly represent a bi-directional data exchange between the drive controller and a periphery of the drive controller, data communication via a field bus interface is necessary. This is a cyclically called process data interface between the drive controller and a peripheral drive controller.

In order to optimize development times and/or production times, it is increasingly important—as in numerous other technical areas—to simulate or virtualize such drive systems, especially before they undergo a real (prototype) manufacturing process. Various simulation methods for simulating a drive behavior of a drive system are already known. Examples include dynamic models and kinematics models of electric drives.

In a dynamic model, a virtualized motor model and/or a virtualized mechanical model and/or a virtualized kinematics model of the electric drive to be simulated are provided depending on the level of detail of the system simulation, so that an actual force value and/or an actual torque value can be provided to the simulation model of the drive controller. The simulation model of the drive controller returns a simulated actual position value in response thereto. In a kinematics model, on the other hand, an actual position value is calculated directly from the simulation model of the drive controller without the need for further external simulation models. Such a kinematics simulation thus serves to visualize a movement behavior of the electric drive and generally comprises a lower level of simulation detail than a dynamic simulation.

Particularly in the dynamic simulation, a solitary simulation of the drive controller is not readily possible, since a simulation model of the drive controller relies on interaction with peripheral system variables, such as an actual force value and/or an actual torque value, in order to reproduce the control behavior as realistically as possible. Communication via a field bus used in reality is generally ruled out, as such periphery variables are not available as real input variables and/or output variables, but would only have to be taken into account in the virtual periphery of the drive controller. This means that a dynamic simulation of a real drive system can only be designed as a complete simulation, in which interaction with system variables peripheral to the drive controller must already be implemented in the overall simulation model.

This is disadvantageous because, for example, a connection and/or adaptation of a simulation model of a drive controller to an external simulation model of drive mechanics and/or an external kinematics model of an electric machine is not readily possible. Instead, a relevant simulation model of a drive controller must be extended and/or supplemented by the respective periphery variable, which again requires additional programming effort. External models may also need to be adapted to a programming language used for the simulation of the drive controller, which increases the susceptibility to systematic errors occurring, which in turn reduces the accuracy of a later simulation result. Also, in the prior art, it is not readily possible to execute a simulation model of a drive controller in a standard software environment of a computer without a physical connection to an electrical machine as standalone software, since a corresponding periphery interaction would first have to be implemented to correctly virtualize the real behavior of the electrical machine and/or of the drive system.

The disclosure is thus based on the task of at least partially overcoming the problems arising in the prior art and in particular making it possible for a simulation model of a drive controller to interact with a controller periphery without the need for a comprehensive adaptation of the simulation model of the drive controller.

The task is solved by a parameterizable, software-implemented interface as disclosed herein.

### SUMMARY

According to the disclosure, a parameterizable, software-implemented interface for data exchange of at least one process variable between a simulation model of a drive controller of an electric drive and a periphery of the drive controller of the electric drive is proposed. The parameterizable, software-implemented interface is preferably used to emulate a field bus interface between a real drive controller of a real drive and a real periphery of the real drive controller.

Furthermore, the disclosure relates to a software-implemented, virtual drive system comprising a simulation model of a drive controller of an electric drive, a simulation model of at least one process variable of a periphery of the drive controller of the electric drive and/or at least one process variable of the periphery of the drive controller of the electric drive, and an interface according to the disclosure, which is set up to transmit the at least one process variable to the simulation model of the drive controller and/or to the periphery. Such a software-implemented, virtualized drive system creates a digital twin of a real drive system that can be used to support the design and/or production preparation of a real drive system. For example, operating modes of the drive system may be simulated without the need to build costly hardware models. The interface also makes it possible to simulate different peripheries of a drive controller, as different virtual models of such peripheries can be connected to the simulation model of the drive controller via the interface. Communication and/or data exchange between the periphery and the simulation model of the drive controller then occurs via the interface.

Meta-information is preferably provided at the interface according to the disclosure, which is based on a field bus communication between a drive controller of a real electric machine and the periphery of the real drive controller. The software-implemented interface virtually provides a virtual counterpart to a real field bus interface. The parametrization allows the virtual interface to be supplied with the at least one process variable as a parameter, which is preferably in a direct operative connection and/or interdependency with the simulation model of the drive controller. A field bus is understood to mean an interface between the drive controller and/or the drive controller and a periphery of the drive controller. It is preferably a cyclically called process data interface between the drive controller and the periphery, wherein the field bus is emulated according to the disclosure. According to the disclosure, a parameterizable interface for a virtual periphery of a virtual engine is provided and implemented on the software side. The interface is preferably described on the software side so that it can be connected to another software component or an external software can be connected to the interface. According to the disclosure, drive logic of a real drive controller is preferably rewritten, in particular as a binary control instruction, in such a way that it runs on a real-time simulation model of a real drive controller.

According to the disclosure, the interface is used to exchange at least one process variable, which does not readily exist in the virtual drive in particular, but is only provided via field bus communication in the real case, between the simulation model of the drive controller and the periphery or environment of the drive controller. The interface according to the disclosure can preferably be parameterized as a function of a simulation depth.

According to the disclosure, a drive logic of a drive controller is preferably configured on the software side, such that it can not only be executed on a computing device of a real drive system, but can also be executed, for example, solitarily or on its own in a standard software environment of a computer without a physical connection to an electric machine and/or another periphery.

A “Drive Software-in-the-Loop” simulation may be provided by the interface and/or the system. This makes it possible to run firmware on a virtual drive hardware, in particular the virtual drive controller, to virtually simulate a behavior of the drive system. This supports the following real-world use cases, among others: A machine design and/or dimensioning through a virtual simulation of the drive behavior as part of the underlying machine simulation; and/or a drive product presentation and training; and/or a virtual drive commissioning by parameterizing the interface to check parameterization and operating modifications and/or a drive design check; and/or a parallel operation of the virtual drive system with a real drive system as a digital twin.

In a kinematics simulation of an electric drive or an electric machine, it is preferably assumed to be ideal and insulated. This is preferably considered in the simulation such that an actual position value of the electric drive is set equal to a target position value of the electric drive. In addition, preferably no control loops and/or filters and/or other periphery variables of a drive controller required and simulated for the electric drive are simulated, as they are also idealized. The user preferably receives an actual position value as a simulated output variable from such a kinematic simulation model. Such a kinematic simulation serves, for example, to map mechanical dimensions of an electric machine and/or product components, for example to be able to perform collision monitoring in the simulation model.

In the dynamic simulation according to the disclosure the behavior of the drive controller of the electric drive is simulated in the simulation model itself. The user preferably provides a relevant motor model, mechanics model and kinematics model independently. The simulation model preferably provides the user with a force target value and/or torque target value via the interface. For this purpose, the simulation model of the drive controller requires an implementation of a simulation model of an electric machine and/or a simulation model of a drive mechanics, so that an actual position value can be returned as an input variable for the simulation model of the drive controller via the interface, in order to preferably close the control loop in this way.

In a preferred embodiment, it is made possible to read the at least one process variable into the simulation model of the drive controller and/or to output the at least one process variable from the simulation model of the drive controller via the interface. This allows bi-directional interaction and/or communication with a virtual periphery of the drive controller. Peripheries are understood to mean any mechanical and/or electrical and/or electronic and/or electromagnetic and/or electromechanical components of a drive system that interact with the drive controller, and that may have a direct or indirect influence on the drive controller during system virtualization.

In a preferred embodiment, the interface can be parameterized as a function of a simulation depth of the simulation model of the drive controller and/or the periphery of the drive controller. In other words, the number and/or configurability of the process variables depends on the level of detail with which the virtual drive system is provided in its entirety. For example, a simulation depth of a simulation model of a drive controller comprising a master controller, an axis controller of the electric drive and a motor controller of the electric drive is greater compared to a simulation model of a drive controller with only one master controller. The same applies to the simulation depth of the periphery, which increases in size the more the virtual periphery corresponds to a real periphery of a particular drive system. The interface can be used to exchange process variables on actuators and sensors that do not actually exist in the virtual drive with an environment, i.e., the periphery in which they are simulated. The process data to be exchanged are preferably dependent on the simulation depth. If the periphery of the drive controller is only mapped by virtualization of the kinematics of the electric drive, the simulation depth is low but correspondingly higher. If an axis control or even a motor control is additionally simulated, the simulation depth increases and with it the parametrization capability of the interface.

In a preferred embodiment, the interface is configured for cyclic data exchange. The interface is therefore preferably configured to exchange the process variables based on a sequence resulting from the content of the process variables. The periphery signals are preferably exchanged with the simulation environment via the cyclically operated interface. The mechanisms used for process data communication are preferably used for this purpose. The data exchange between the simulation model of the drive controller and the periphery of the drive controller is preferably carried out in a bi-directional manner. This is preferable because a simulation model of a drive controller preferably incorporates signals from its periphery in the execution of the control algorithm. Examples include a DC link voltage and/or signals from digital inputs and/or temperature sensor signals. Alternatively or additionally, it is preferred when signals are transmitted from the simulated drive controller to its periphery. Examples include signals from digital outputs and/or a drawn power.

In a preferred embodiment, the interface can be parameterized by configuration of the at least one process variable as an input variable or as an output variable. Other parametrizations can also occur, as will be explained in more detail below.

In a preferred embodiment, the at least one process variable is assigned an internationalized domain name (IDN), on the basis of which a data exchange, in particular an exchange direction and/or a cycle time, can be parameterized via the interface. The respective IDN is preferably configurable. The respective IDN preferably comprises a predetermined number of configurable bytes, for example 16 bytes. A number of assignable IDNs for the interface according to the disclosure are preferably limited.

For example, the following parameters are used for the operation of the interface according to the disclosure:

As shown in Table 1, an IDN comprises the following structure, for example: P-0-1890.0/1.8 (VPL: control word connection).

TABLE 1

| Bit | Name/function |
|---|---|
| 0 | Data status |
| | 0: Data producer (provider of the at least one process variable) does not yet enter |
| | any valid process variables. |
| | 1: Data producer enters valid process variables. The receiver of the at least one |
| | process variable can accept the process variables by toggling bit 1 or bit 12. |
| 4 | Data exchange direction control |
| | 0: For this connection, the production or consumption of the at least one process |
| | variable is activated. Error monitoring is active. |
| | 1: For this connection, the production or consumption of the at least one process |
| | variable is deactivated. Errors are not monitored and do not result in an error |
| | response. |
| 12 . . . 15 | Counter |
| | The initial value of this counter is 0 |
| | any change to this counter will report new application data in the connection and |
| | the application data can be processed; |
| | with a clock synchronous or cyclic connection, this counter is always to be |
| | increased in the respective communication cycle; |
| | for a non-cyclic connection, a change to this |
| | counter triggers a watchdog, i.e., the monitoring time is restarted after this |
| | counter is changed. This counter may be increased at most once per generator |
| | cycle time and at least once per monitoring time after the data producer (bit 0) |
| | has already been set to 1; |
| | Bit 12 is preferably equal to Bit 1 (new data). |

In a preferred embodiment, the at least one process variable comprises an output variable of an external simulation model, in particular a kinematic model of the electric drive and/or a mechanical model of the electric drive and/or a motor model of the electric drive, and/or wherein the at least one process variable comprises an input variable into an external simulation model, in particular into a kinematic model of the electric drive and/or into a mechanics model of the electric drive and/or into a motor model of the electric drive. The above list is not exhaustive and is not intended to be restrictive.

In a preferred embodiment, the at least one process variable comprises a DC link voltage and/or a DC link current and/or a signal from a throttle device and/or a signal from a probe input and/or a signal of a digital and/or analog input and/or a temperature sensor signal and/or a sensor signal and/or a heat sink temperature sensor signal and/or a diagnostic LED control signal and/or a signal from an output of the drive controller, in particular a target position value and/or a target torque value and/or a target force value and/or a motor voltage value, and/or a signal from an input of the drive controller, in particular, an actual position value and/or a motor current value. The above statements are also not to be understood as restrictive. It is understood that the process variables can also occur in any combination and, depending on the application, can be transmitted from the simulation model of the drive controller to the periphery or from the periphery to the simulation model of the drive controller via the interface. The process variables are preferably not only transmitted through the interface, but can also be parameterized through it. The interface is preferably parameterized by configuring a data structure of the at least one process variable for defining a state of the at least one process variable. For example, a determination of a validity of the process variable can be made. Alternatively or additionally, a data flow direction of the process variable and/or error monitoring of the process variable can be carried out during transmission via the interface. A counter may also be configured to monitor the interface communication. For example, the at least one process variable may be given a status of “initialize” or “prepare” or “ready” or “produce” or “stopped” or “waiting” as an attribute.

In a preferred embodiment of the drive system, the at least one process variable comprises a target position value that is transmitted to the periphery via the interface as the output variable of the simulation model of the drive controller, wherein the periphery preferably comprises a kinematic simulation model of the electric drive, into which the transmitted target position value is incorporated as the input variable. Based on the target position value, the kinematic simulation model can perform, for example, a kinematic simulation of the electric drive. This preferably describes the use of the interface according to the disclosure in a kinematic simulation of a drive system with an open loop. Such a drive system includes a comparatively low simulation depth.

In a preferred embodiment of the drive system, the kinematic simulation model of the electric drive is configured to output an actual position value as an output variable, which is transmitted to the simulation model of the drive controller via the interface and enters it as an input variable in order to close the control loop. This preferably describes the use of the interface according to the disclosure in a kinematic simulation of a drive system with a closed loop.

In a preferred embodiment of the drive system, the at least one process variable comprises a target torque value and/or a target force value, wherein the periphery comprises a motor simulation model of the electric drive, and wherein the simulation model of the drive controller comprises a simulation model of an axis controller of the electric drive, which is set up for transmitting the target torque value and/or the target force value as the output variable to the motor simulation model via the interface, wherein the motor simulation model is configured to calculate an actual position value as an output variable based on the target torque value and/or the target force value and to transmit it via the interface as the at least one process variable to the simulation model of the drive controller, in particular to the simulation model of the axis controller.

In a preferred embodiment of the drive system, the at least one process variable comprises a motor voltage and/or a motor frequency, wherein the periphery comprises a motor simulation model of the electric drive, and wherein the simulation model of the drive controller comprises a simulation model of a motor controller of the electric drive, which is set up for transmitting the motor voltage and/or motor frequency as the output variable to the motor simulation model via the interface, wherein the motor simulation model is configured to calculate an actual position value as an output variable based on the motor voltage and/or the motor frequency and to transmit it via the interface as the at least one process variable to the simulation model of the drive controller, in particular to the simulation model of the motor controller. Such a drive system is particularly characterized by a high simulation depth.

The described embodiments and developments can be combined with one another as desired.

Further possible embodiments, developments, and implementations of the disclosure also include not explicitly mentioned combinations of features of the disclosure described above or below with respect to exemplary embodiments.

### BRIEF DESCRIPTION OF THE DRAWINGS

The accompanying drawings are intended to provide a better understanding of the embodiments of the disclosure. The drawings illustrate embodiments and, in connection with the description, serve to explain principles and concepts of the disclosure.

Further embodiments and many of the specified advantages will emerge with reference to the drawings. The elements shown in the drawings are not necessarily drawn to scale with respect to one another.

The FIGURE shows a schematic block diagram of a software-implemented, virtual drive system having an interface according to the disclosure.

Identical reference signs denote identical or functionally identical elements, parts, or components, unless stated otherwise.

### DETAILED DESCRIPTION

The FIGURE shows a schematic structure of a software-implemented virtual drive system 100. The virtual drive system 100 comprises a simulation model of a drive controller 10 of an electric drive that is connected to a periphery 14 of the drive controller 10 via a parameterizable, software-implemented interface 12.

Depending on the application, the simulation model of the drive controller 10 can comprise different simulation depths or a different depth of detail. According to the FIGURE, for example, the simulation model of the drive controller 10 comprises a sub-model of a master controller 16 which is coupled to a control command generator 18. Furthermore, the simulation model of the drive controller 10 comprises a simulation model of an axis controller 20, as well as a simulation model of a motor controller 22. Furthermore, the simulation model of the drive controller 10 comprises a sub-simulation model of a motor protection 24, a sub-model of a component protection 26, a sub-simulation model of a particularly local input-output interface 28, and a sub-simulation model of a power supply controller 30. The simulation models and/or sub-simulation models 16 to 30 can each transmit data and/or signals in the form of at least one process variable to the periphery 14 and/or receive data and/or signals in the form of at least one process variable from the periphery 14 via the interface 12. Several voltages (U_{uv, w}; U_{L1,2,3}; U__{DC}) and currents (I_{u,v}; I_{u,v,w}) are indicated as exemplary process variables or exchange variables in the FIGURE.

Depending on the application, the periphery can be depicted or virtualized at different simulation depths or with different depths of detail. According to the FIGURE, the periphery of the drive controller is simulated with a high level of detail, which is already very close to the physical and/or electrical and/or electronic and/or electromagnetic behavior of an electric machine or simulated electric drive.

The periphery 14 comprises a motor simulation model 32 of the electric drive, a mechanical simulation model 34 of the electric drive, and a kinematic simulation model 36 of the electric drive. Furthermore, the periphery comprises a simulation model of a drive train 38 communicatively coupled to the sub-model of a component protection 26 via interface 12. Furthermore, the periphery comprises an input-output simulation model 40 communicatively coupled to the kinematics simulation model 36 and communicatively coupled to the sub-model of the local input-output interface 28 via the interface 12. Furthermore, the periphery 14 comprises a simulation model of a particularly regenerative power supply 42. The simulation model of the power supply 42 is subdivided into various sub-simulation models, by way of example. For example, the simulation model of the power supply 42 comprises a simulation model of a power supply choke 44, and a simulation model of a supply network 46. The simulation model of the power supply choke 44 is communicatively coupled to the simulation model of the supply network 46. The simulation model of the power supply choke 44 is communicatively coupled to the sub-simulation model of the power supply controller 30 via the interface 12, wherein the process variables U_{uv,w}; U_{L1,2,3} and I_{u,v} are transmitted via the interface. Furthermore, the simulation model of the power supply 42 comprises a sub-simulation model of a DC link capacitor 48 communicatively coupled to the sub-simulation model of the power supply controller 30 via the interface 12.

The data exchange of the process variables as well as an exchange direction is indicated in the FIGURE by dashed arrows.

What is claimed is:

1. A parameterizable software-implemented interface for data exchange of at least one process variable between a simulation model of a drive controller of an electric drive and a periphery of the drive controller of the electric drive.

2. The interface according to claim 1, wherein the interface is configured to read the at least one process variable into the simulation model of the drive controller and/or to output the at least one process variable from the simulation model of the drive controller.

3. The interface according to claim 1, wherein the interface is parameterized as a function of a simulation depth of the simulation model of the drive controller and/or of the periphery of the drive controller.

4. The interface according to claim 1, wherein the interface is configured for cyclic data exchange.

5. The interface according to claim 1, wherein the interface is parameterized by configuration of the at least one process variable as an input variable or as an output variable.

6. The interface according to claim 1, wherein:
the at least one process variable comprises an output variable of an external simulation model including (i) a kinematics model of the electric drive, (ii) a mechanics model of the electric drive, and/or (iii) a motor model of the electric drive, and/or
the at least one process variable comprises an input variable into the external simulation model including (i) the kinematics model of the electric drive, (ii) the mechanics model of the electric drive, and/or (iii) the motor model of the electric drive.

7. The interface according to claim 1, wherein the at least one process variable comprises a DC link voltage and/or a signal from a throttle device and/or a DC link current and/or a signal from a probe input and/or a signal of a digital and/or analog input and/or a temperature sensor signal and/or a sensor signal and/or a heat sink temperature sensor signal and/or a diagnostic LED control signal and/or a signal from an output of the drive controller, in particular a target position value and/or a target torque value and/or a target force value and/or a motor voltage value, and/or a signal from an input of the drive controller, in particular, an actual position value and/or a motor current value.

8. The interface according to claim 1, wherein the interface is parameterized by configuring a data structure of the at least one process variable for defining a state of the at least one process variable.

9. A software-implemented, virtual drive system comprising:
a simulation model of a drive controller of an electric drive;
a simulation model of at least one process variable of a periphery of the drive controller of the electric drive and/or at least one process variable of the periphery of the drive controller of the electric drive; and
a parameterizable software-implemented interface for data exchange of the at least one process variable between the simulation model of the drive controller and the periphery of the drive controller, wherein the interface is configured to transmit the at least one process variable to the simulation model of the drive controller and/or to the periphery.

10. The drive system according to claim 9, wherein:
the at least one process variable comprises a target position value that is transmitted to the periphery via the interface as an output variable of the simulation model of the drive controller, and
the periphery preferably comprises a kinematic simulation model of the electric drive, into which the transmitted target position value is incorporated as an input variable.

11. The drive system according to claim 10, wherein the kinematic simulation model of the electric drive is configured to output an actual position value as another output variable, which is transmitted to the simulation model of the drive controller via the interface and enters it as another input variable in order to close the control loop.

12. The drive system according to claim 9, wherein:
the at least one process variable comprises a target torque value and/or a target force value,
the periphery comprises a motor simulation model of the electric drive,
the simulation model of the drive controller comprises a simulation model of an axis controller of the electric drive, which is set up for transmitting the target torque value and/or the target force value as an output variable to the motor simulation model via the interface, and
the motor simulation model is configured to calculate an actual position value as another output variable based on the target torque value and/or the target force value and to transmit it via the interface as the at least one process variable to the simulation model of the drive controller.

13. The drive system according to claim 9, wherein:
the at least one process variable comprises a motor voltage and/or a motor frequency,
the periphery comprises a motor simulation model of the electric drive,
the simulation model of the drive controller comprises a simulation model of a motor controller of the electric drive, which is set up for transmitting the motor voltage and/or motor frequency as an output variable to the motor simulation model via the interface, and
the motor simulation model is configured to calculate an actual position value as another output variable based on the motor voltage and/or the motor frequency and to transmit it via the interface as the at least one process variable to the simulation model of the drive controller.
